(19) United States
(12) Patent Application Publication
(10) Pub. No.: US 2026/0143926 A1
(43) Pub. Date: May 21, 2026

(54) DISPLAY DEVICE

(71) Applicant: LG Display Co., Ltd., Seoul (KR)

(72) Inventor: MyeongHak HYUN, Paju-si (KR)

(73) Assignee: LG Display Co., Ltd., Seoul (KR)

(21) Appl. No.: 19/368,691

(22) Filed: Oct. 24, 2025

(30) Foreign Application Priority Data
Nov. 20, 2024 (KR) 10-2024-0166016

(51) Int. Cl. H10K 59/123; H10K 59/122

(52) U.S. Cl. CPC H10K 59/123; H10K 59/122

(57) ABSTRACT

An embodiment of the present disclosure provides a display device includes a substrate including a first groove on a first surface and a second groove on a second surface opposite to the first surface, a thin film transistor disposed in the first groove of the substrate, and an upper organic light emitting element disposed in the second groove of the substrate, wherein the thin film transistor and the upper organic light emitting element are electrically connected through a via hole, and the via hole is formed to penetrate the first groove and the second groove.

### CROSS-REFERENCE TO RELATED APPLICATION

This application claims the benefit of priority of the Republic of Korea Patent Application No. 10-2024-0166016 filed on Nov. 20, 2024, which is hereby incorporated by reference in its entirety.

### BACKGROUND

### Technical Field

The present disclosure relates to a display device.

### Discussion of the Related Art

As the information society develops, the demand for display devices for displaying images is increasing in various forms. Accordingly, various display devices such as liquid crystal displays (LCD), plasma display panels (PDP), and organic light emitting displays (OLED) are being utilized recently.

Among display devices, organic light emitting display devices are self-luminous, and have superior viewing angles and contrast ratios compared to liquid crystal displays (LCD), and do not require a separate backlight, making them lightweight and thin, and have the advantage of low power consumption. In addition, organic light emitting display devices may be driven by low direct current voltage, have a fast response speed, and have the advantage of low manufacturing costs.

An organic light emitting display device has a structure in which an organic light emitting element including an emission layer is disposed between a cathode that injects electrons and an anode that injects holes. An organic light emitting display device is a display device that utilizes the principle that when electrons generated from the cathode and holes generated from the anode are injected into the emission layer, the injected electrons and holes combine to generate excitons, and the generated excitons fall from an excited state to a ground state to emit light.

The conventional display devices form organic light emitting display devices and thin film transistors, driving circuits, and wiring for driving the organic light emitting display devices on the upper or lower surface of a substrate, so there is a limit to implementing the display devices with a thinner thickness.

### SUMMARY

Accordingly, embodiments of the present disclosure are directed to a display device that substantially obviates one or more of the problems due to limitations and disadvantages of the related art.

An aspect of the present disclosure is to provide a thin display device by forming a groove on the upper or lower surface of a substrate and forming an organic light emitting element, a thin film transistor, a driving circuit, and wiring in the groove.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a first groove on a first surface and a second groove on a second surface opposite to the first surface, a thin film transistor disposed in the first groove of the substrate, and an upper organic light emitting element disposed in the second groove of the substrate, wherein the thin film transistor and the upper organic light emitting element are electrically connected through a via hole, and the via hole is formed to penetrate the first groove and the second groove.

In another aspect, a display device comprises a substrate a substrate including a first groove on a first surface and two or more second grooves on a second surface opposite to the first surface, a thin film transistor disposed in the first groove of the substrate, and a first light emitting element and a second light emitting element respectively disposed in adjacent second grooves, wherein each of the first light emitting element and second light emitting element includes a first electrode disposed in the second groove, an emission layer on the first electrode, and a second electrode on the emission layer, wherein the second electrodes of the first light emitting element and second light emitting element are continuously formed.

In another aspect, a display device comprises a substrate defining a display area and a non-display area, a plurality of subpixels disposed in the display area and a first thin film transistor configured to drive the plurality of subpixels, and a gate driver circuit disposed in the non-display area, wherein the first thin film transistor is disposed in a first groove on a first surface of the substrate, wherein the plurality of subpixels are respectively disposed in a plurality of second grooves on a second surface of the substrate, and wherein the first thin film transistor and the plurality of subpixels are electrically connected through a via hole that connects the first groove and the plurality of second grooves.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1A is a schematic perspective view of a display device according to one embodiment of the present disclosure. In this case, FIG. 1A relates to a first side of the display device according to one embodiment of the present disclosure.

FIG. 1B is a plan view of a display device according to one embodiment of the present disclosure.

FIG. 2A is a schematic perspective view of a display device according to one embodiment of the present disclosure. In this case, FIG. 2A relates to a second side of the display device according to one embodiment of the present disclosure.

FIG. 2B is a plan view of a display device according to one embodiment of the present disclosure.

FIG. 3 is a cross-sectional view of a display device according to one embodiment of the present disclosure. In this case, FIG. 3 relates to cross-sections II′ and II-II′ of FIG. 2B.

FIG. 4A to FIG. 4E are process cross-sectional views illustrating a method for manufacturing a display device according to one embodiment of the present disclosure. In this case, FIG. 4A to FIG. 4E relate to cross-sections I-I′ and II-II′ of FIG. 2B.

FIG. 5 is a cross-sectional view of a display device according to another embodiment of the present disclosure. In this case, FIG. 5 relates to cross-sections I-I′ and II-II′ of FIG. 2B.

FIG. 6 is a cross-sectional view of a display device according to another embodiment of the present disclosure. In this case, FIG. 6 relates to cross-sections II′ and II-II′ of FIG. 2B.

FIG. 7 is a plan view of a display device according to another embodiment of the present disclosure.

FIG. 8 is a plan view of a display device according to another embodiment of the present disclosure.

FIG. 9 is a cross-sectional view of a display device according to another embodiment of the present disclosure. In this case, FIG. 9 relates to cross-sections I-I′ and III-III′ of FIG. 8.

### DETAILED DESCRIPTION

The advantages and features of the present disclosure, and the methods for achieving them, will become clear with reference to the embodiments described in detail below together with the accompanying drawings. However, the present disclosure is not limited to the embodiments disclosed below, but may be implemented in various different forms, and these embodiments are disposed only to make the disclosure of the present disclosure complete and to fully inform a person having ordinary skill in the art to which the present disclosure belongs of the scope of the invention, and the present disclosure is defined only by the scope of the claims.

The shapes, sizes, ratios, angles, numbers, etc. disclosed in the drawings for explaining embodiments of the present disclosure are exemplary, and therefore the present disclosure is not limited to the matters illustrated. Like reference numerals refer to like elements throughout the specification. In addition, in describing the present disclosure, if it is determined that a detailed description of a related known technology may unnecessarily obscure the gist of the present disclosure, the detailed description will be omitted. When the terms “includes,” “has,” “consists of,” etc. are used in this specification, other parts may be added unless “only” is used. When a component is expressed in the singular, it includes a case where the plural is included unless there is a specifically explicit description.

When interpreting a component, it is interpreted as including the error range even if there is no separate explicit description.

When describing a positional relationship, for example, when the positional relationship between two parts is described as ‘on ˜’, ‘upper ˜’, ‘lower ˜’, ‘next to ˜’, etc., one or more other parts may be located between the two parts, unless ‘right’ or ‘directly’ is used.

When describing a temporal relationship, for example, when describing a temporal relationship using phrases such as ‘after’, ‘following’, ‘next to’, or ‘before’, it can also include cases where there is no continuity, as long as ‘right away’ or ‘directly’ is not used.

Although the terms first, second, etc. are used to describe various components, these components are not limited by these terms. These terms are only used to distinguish one component from another. Accordingly, a first component referred to below may also be a second component within the technical concept of the present disclosure.

The individual features of the various embodiments of the present disclosure may be partially or wholly combined or combined with each other, and may be technically linked and driven in various ways, and each embodiment may be implemented independently of each other or may be implemented together in a related relationship.

Hereinafter, preferred embodiments of the present disclosure will be described in detail with reference to the drawings.

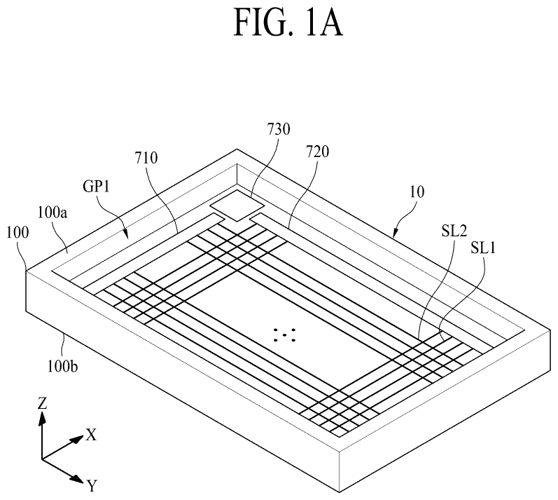

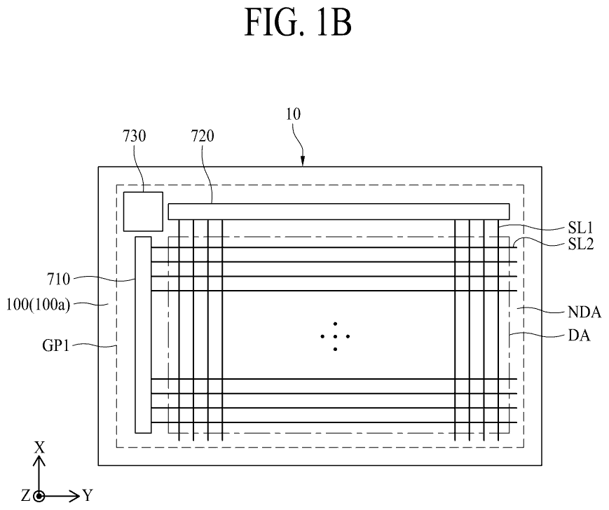

FIG. 1A is a schematic perspective view of a display device according to one embodiment of the present disclosure, and FIG. 1B is a plan view of the display device according to one embodiment of the present disclosure. In this case, FIG. 1A and FIG. 1B relate to a first side of the display device according to one embodiment of the present disclosure.

Below, the X-axis represents the direction parallel to the scan line, the Y-axis represents the direction parallel to the data line, and the Z-axis represents the height direction of the display device.

The display device according to one embodiment of the present disclosure has been described mainly as being implemented as an organic light emitting display, but may also be implemented as a liquid crystal display, a plasma display panel (PDP), a quantum dot light emitting display (QLED), or an electrophoresis display.

As may be seen in FIG. 1A, a display device according to one embodiment of the present disclosure includes a display panel 10. In this case, the display panel 10 includes a substrate 100 and a gate driving unit 710, a data driving unit 720, a timing control unit 730, a first signal line SL1, and a second signal line SL2 disposed on the substrate 100.

The substrate 100 may be disposed with a first groove portion GP1 formed by removing a portion of a first surface 100a of the substrate 100. The first surface 100a of the substrate 100 may be formed concavely by the first groove portion GP1. The first surface 100a may include surfaces having different heights in a first direction Z, for example, a vertical direction.

According to one embodiment of the present disclosure, the gate driver 710, the data driver 720, the timing control unit 730, the first signal line SL1 and the second signal line SL2 may be disposed in a concave portion of the first surface 100a of the substrate 100. In detail, the gate driver 710, the data driver 720, the timing control unit 730, the first signal line SL1 and the second signal line SL2 may be formed in the first groove portion GP1. By forming them in this manner, the gate driver 710, the data driver 720, the timing control unit 730, the first signal line SL1 and the second signal line SL2 are formed inside the substrate 100, thereby making it possible to implement a thin height or thickness in the first direction Z of the display device according to one embodiment of the present disclosure.

As may be seen in FIG. 1B, according to one embodiment of the present disclosure, the gate driver 710, the data driver 720, the timing controller 730, the first signal line SL1 and the second signal line SL2 may be formed in the first groove portion GP1. Without being limited thereto, various thin film transistors for driving pixels formed by intersecting the first signal line SL1 and the second signal line SL2 may also be formed in the first groove portion GP1.

According to one embodiment of the present disclosure, the display panel 10 of the display device may be divided into a display area DA in which a plurality of pixels are formed to display an image and a non-display area NDA in which an image is not displayed. In the display area DA, specifically, in the display area DA on the first surface 100a of the substrate 100, wiring and electrodes for driving a plurality of pixels are formed while the first signal line SL1 and the second signal line SL2 intersect each other.

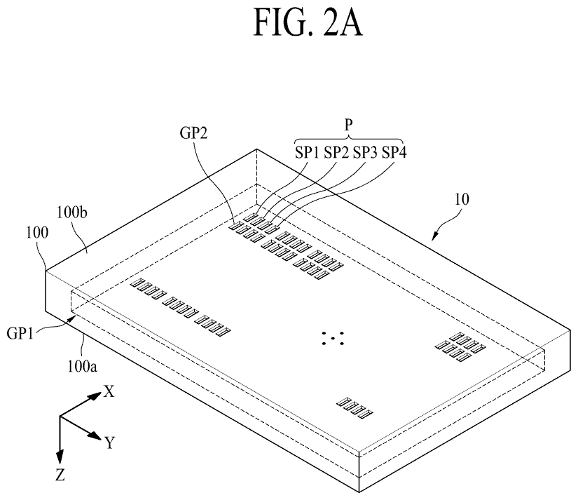

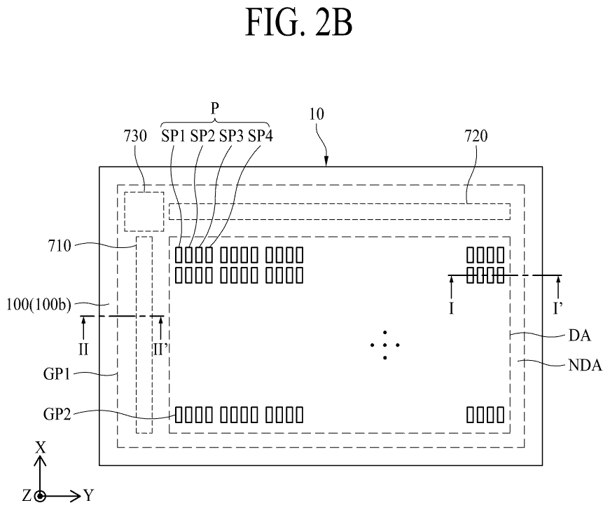

The first signal line SL1 may extend in a third direction e.g., in the X-axis direction and may intersect the second signal line SL2 in the display area DA. The second signal line SL2 may extend in a second direction e.g., in the Y-axis direction in the display area DA. The plurality of pixels (see P of FIGS. 2A and 2B) may be disposed to overlap an area in which the first signal line SL1 is disposed or an area in which the first signal line SL1 and the second signal line SL2 intersect. The first signal line SL1 may be, for example, a data line that transmits a data signal from the data driver 720, and the second signal line SL2 may be, for example, a gate line that transmits a gate signal from the gate driver 710. Meanwhile, without being limited thereto, the first signal line SL1 extending in the third direction X and the second signal line SL2 extending in the second direction Y may be, for example, a power line for supplying a high-potential voltage VDD, a common power line for supplying a low-potential voltage VSS, and a reference line for supplying a reference voltage Vref.

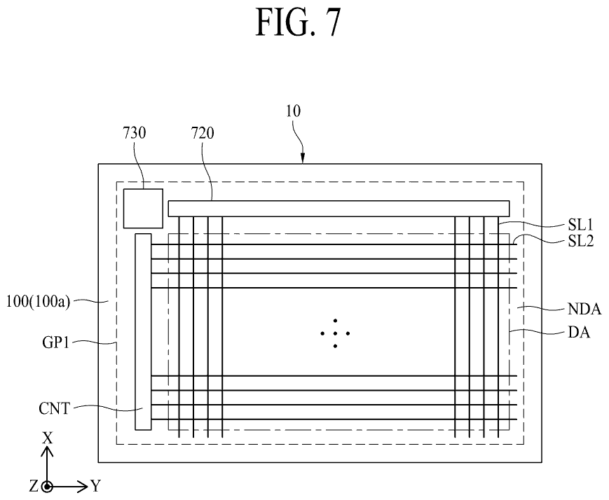

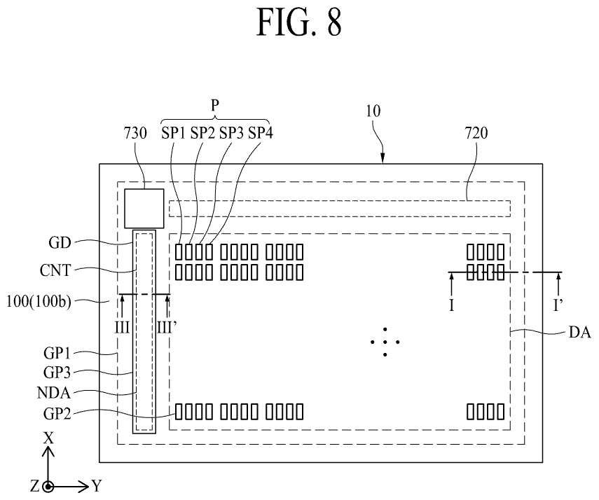

The gate driving unit 710 is formed in the first groove portion GP1. The gate driving unit 710 includes a plurality of thin film transistors, and thus may be formed in a gate in panel GIP structure. Meanwhile, the present disclosure is not limited thereto, and as in the embodiments of FIG. 7 and FIG. 8, the gate driving unit 710 may be formed in the first groove portion GP1 of the substrate 100 in the form of an integrated circuit.

When the gate driving unit 710 is formed as a GIP structure, the gate driving unit 710 may include a shift register.

The shift register sequentially supplies gate pulses to the second signal lines SL2, for example, gate lines GL, for one frame using a start signal and a gate clock transmitted from the timing control unit 730. Here, one frame refers to a period during which one image is output through the display panel 10. The gate pulse has a turn-on voltage capable of turning on a switching element thin film transistor disposed in a circuit for driving a pixel.

Additionally, the shift register supplies a gate off signal capable of turning off a switching element to the second signal line SL2, for example, a gate line, during the remaining period during one frame when the gate pulse is not supplied. The gate pulse and the gate off signal may be collectively referred to as a gate signal GS.

The data driving unit 720 supplies a data voltage to the first signal line SL1, for example, data lines, of the display panel 10. In detail, the data driving unit 720 converts image data RGB input from the timing control unit 730 into an analog data voltage and supplies the data voltage to the first signal line SL1, for example, data lines.

The timing control unit 730 controls the gate driving unit 710 and the data driving unit 720. The timing control unit 730 uses a signal supplied from an external system not shown to output a gate control signal GCS for controlling the gate driving unit 710 and a data control signal DCS for controlling the data driving unit 720. In addition, the timing control unit 730 samples input image data input from an external system, rearranges it, and supplies rearranged digital image data RGB to the data driving unit 720.

The above gate control signal GCS includes a gate start pulse GSP, a gate shift clock GSC, a gate output enable signal GOE, a start signal Vst, and a gate clock GCLK. In addition, the gate control signal GCS may include control signals for controlling a shift register.

The above data control signal DCS includes a source start pulse SSP, a source shift clock signal SSC, a source output enable signal SOE, a polarity control signal POL, or the like.

FIG. 2A is a schematic perspective view of a display device according to one embodiment of the present disclosure, and FIG. 2B is a plan view of a display device according to one embodiment of the present disclosure. In this case, FIG. 2A and FIG. 2B relate to a second side of the display device according to one embodiment of the present disclosure.

As may be seen in FIG. 2A, a display device according to an embodiment of the present disclosure may include a display panel 10, and a plurality of second grooves GP2 formed by removing a portion of a second surface 100b of a substrate 100 may be disposed on a rear surface of the display panel 10. An organic light emitting element may be formed in the plurality of second grooves GP2. Accordingly, the plurality of second grooves GP2 may form a plurality of pixels P.

Each of the above plurality of pixels P may include a first sub pixel SP1 to a fourth sub pixel SP4.

Since the plurality of pixels P are disposed in the plurality of second grooves GP2 formed on the second surface 100b of the substrate 100, the thickness of the display device according to one embodiment of the present disclosure may be implemented thinly.

As may be seen in FIG. 2B, the plurality of second grooves GP2 are disposed in the second direction Y and the third direction X on the second surface 100b of the substrate 100. Accordingly, the plurality of pixels P disposed in the plurality of second grooves GP2 may be arranged along the second direction Y and the third direction X on the second surface 100b of the substrate 100. In this case, the plurality of pixels P may include a first sub pixel SP1, a second sub pixel SP2, a third sub pixel SP3, and a fourth sub pixel SP4 that display different colors. An organic light emitting element may be formed in one of the second grooves GP2 among the plurality of second grooves GP2, and the one of the second grooves GP2 in which the organic light emitting element is formed may constitute one of the sub pixels among the first sub pixel SP1 to the fourth sub pixel SP4.

The plurality of pixels P may include a first sub pixel SP1 to a fourth sub pixel SP4. The first sub pixel SP1 to the fourth sub pixel SP4 may, for example, display red R, green G, blue B, and white W, respectively, but are not limited thereto, and the color and arrangement of light displayed by the first sub pixel SP1 to the fourth sub pixel SP4 may be variously changed according to common sense in the art.

According to one embodiment of the present disclosure, the plurality of second grooves GP2 are formed in the display area DA, and the plurality of second grooves GP2 may not be formed in the non-display area NDA. Although not specifically illustrated, the first signal line (see SL1 of FIG. 1B) and the second signal line (see SL2 of FIG. 1B) may be provided to correspond to an area where they intersect each other. In this case, signals applied from the first signal line (see SL1 of FIG. 1B) and the second signal line (see SL2 of FIG. 1B) drive the organic light emitting element disposed in the second grooves GP2, so that the plurality of pixels P can display an image.

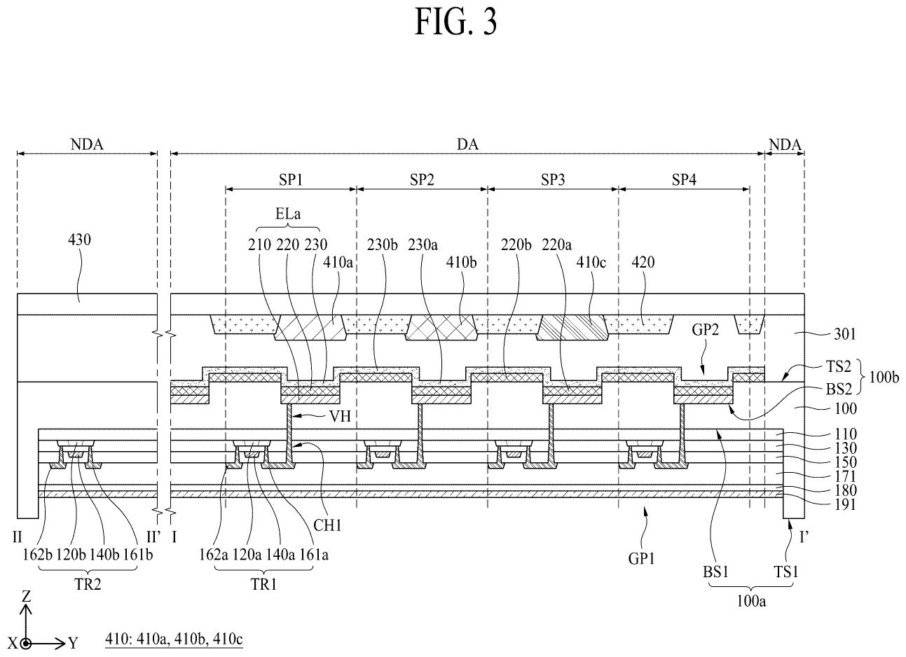

FIG. 3 is a cross-sectional view of a display device according to one embodiment of the present disclosure. In this case, FIG. 3 relates to cross-sections I-I′ and II-II′ of FIG. 2B.

As may be seen in FIG. 3, a display device according to an embodiment of the present disclosure may include a substrate 100, a buffer layer 110, a first thin film transistor TR1, a second thin film transistor TR2, a gate insulating layer 130, an interlayer insulating layer 150, a first planarization layer 171, an adhesive member 180, a lower encapsulation layer 191, and an upper organic light emitting element ELa, an upper color filter 410, an upper black matrix 420, and a cover glass 430.

According to one embodiment of the present disclosure, the buffer layer 110, the first thin film transistor TR1, the second thin film transistor TR2, the gate insulating layer 130, the interlayer insulating layer 150, the first planarization layer 171, the adhesive member 180, and the lower encapsulation layer 191 may be disposed in a first groove portion GP1 formed on the first surface 100a of the substrate 100. Furthermore, the upper organic light emitting element ELa may be formed on the second surface 100b of the substrate 100. In detail, the upper organic light emitting element ELa may be disposed inside the second groove portion GP2 formed on the second surface 100b. Furthermore, the cover glass 430 on which the upper color filter 410 and the upper black matrix 420 are formed may be disposed to cover the second surface 100b of the substrate 100.

The substrate 100 may be made of glass or plastic. In particular, the substrate 100 may be made of a transparent plastic having flexible property, for example, polyimide. When polyimide is used as the substrate 100, considering that a high temperature deposition process is performed on the substrate 100, a heat resistant polyimide that can withstand high temperatures may be used. According to one embodiment of the present disclosure, a first groove portion GP1 overlapping a non-display area NDA and a display area DA may be formed on a first surface 100a of the substrate 100, and a plurality of second groove portions GP2 overlapping the display area DA but not overlapping the non-display area NDA may be formed on a second surface 100b of the substrate 100. In this case, the length in the second direction Y, for example, the horizontal direction, of the first groove portion GP1 may be greater than the length in the second direction Y of any one of the plurality of second groove portions GP2.

By forming the first groove portion GP1, the first surface 100a of the substrate 100 includes a first upper surface TS1 disposed in an area where the first groove portion GP1 is not formed and a first bottom surface BS1 provided at the bottom of the first groove portion GP1. In this case, the first bottom surface BS1 is provided to be relatively adjacent to the second surface 100b compared to the first upper surface TS1.

The buffer layer 110 may be formed on the substrate 100. In detail, the buffer layer 110 may be formed in the first groove portion GP1 of the first surface 100a of the substrate 100, and may be formed on the first bottom surface BS1 of the first groove portion GP1. The buffer layer 110 may block air and moisture to protect the first thin film transistor TR1 and the second thin film transistor TR2. The buffer layer 110 may be formed of an inorganic insulating material, such as silicon oxide, silicon nitride, or a metal oxide, but is not necessarily limited thereto, and may be formed of an organic insulating material.

Meanwhile, although not specifically illustrated, a light blocking layer may be formed between the substrate 100 and the buffer layer 110. In this case, the light blocking layer can prevent light entering from the bottom of the substrate 100 from reaching the active layer 120.

The first thin film transistor TR1 and the second thin film transistor TR2 may be formed on the buffer layer 110. Accordingly, the first thin film transistor TR1 and the second thin film transistor TR2 may be formed within the first groove portion GP1.

The first thin film transistor TR1 may be disposed in an area overlapping the display area DA, and the first thin film transistor TR1 may be electrically connected to each of the upper organic light emitting elements ELa disposed in the first sub pixel SP1 to the fourth sub pixel SP4 to control the operation of the upper organic light emitting element ELa. The first thin film transistor TR1 may be, for example, a driving thin film transistor, but is not limited thereto.

The second thin film transistor TR2 may be disposed in an area overlapping the non-display area NDA. The second thin film transistor TR2 may be any one of a plurality of thin film transistors that perform various functions and are disposed in the gate driver (see 710 of FIG. 1A to FIG. 2B) disposed in the non-display area NDA. For example, the second thin film transistor TR2 may be any one of the thin film transistors disposed in a full-up node Q, a full-down node QB, a node control unit NC, and a buffer unit (Buffer). The second thin film transistor TR2 may apply a gate signal generated in the gate driver (see 710 of FIGS. 1A to 2B) to a gate electrode of any one of the plurality of thin film transistors disposed in the display area DA.

The first thin film transistor TR1 may be formed by including a first active layer 120a, a first gate electrode 140a, a first source electrode 161a, and a first drain electrode 162a, and the second thin film transistor TR2 may be formed by including a second active layer 120b, a second gate electrode 140b, a second source electrode 161b, and a second drain electrode 162b.

The first active layer 120a and the second active layer 120b may be formed on the buffer layer 110. The first active layer 120a and the second active layer 120b may be formed of a semiconductor material, for example, one of amorphous silicon (a-Si), polycrystalline silicon (Poly Si), and oxide semiconductor Oxide materials.

The first active layer 120a and the second active layer 120b may each include a channel part, a first connection part disposed on one side of the channel part, for example, on the left side, and a second connection part disposed on the other side of the channel part, for example, on the right side. In this case, since the first connection part and the second connection part are not covered by the first gate electrode 140a and/or the second gate electrode 140b, they may be conductive and have higher conductivity characteristic than the channel part.

The gate insulating layer 130 may be formed on the first active layer 120a and the second active layer 120b. The gate insulating layer 130 may be formed on the entire surface of the substrate 100, but is not limited thereto. A portion of the gate insulating layer 130 may be patterned so that one end and the other end of the gate insulating layer 130 correspond to one end and the other end of the first gate electrode 140a and the second gate electrode 140b, respectively.

The gate insulating layer 130 may include, but is not limited to, a silicon nitride film (SiNx) or a silicon oxide film (SiOx). The gate insulating layer 130 may be formed of a single layer or multiple layers including an inorganic insulating material and/or an organic insulating material.

The gate electrode 140a and the second gate electrode 140b may be formed on the gate insulating layer 130.

The gate electrode 140a and the second gate electrode 140b may include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 140 may have a structure including one metal layer or a multilayer film structure including at least two metal layers each having different physical property.

The interlayer insulating layer 150 may be formed on the gate electrode 140a and the second gate electrode 140b. The interlayer insulating layer 150 insulates between the first gate electrode 140a and the first source electrode 161a, and further insulates between the first gate electrode 140a and the first drain electrode 162a. In addition, the interlayer insulating layer 150 insulates between the second gate electrode 140b and the second source electrode 161b, and further insulates between the second gate electrode 140b and the second drain electrode 162b. The interlayer insulating layer 150 may be formed of a single layer or a plurality of layers including an inorganic insulating material and/or an organic insulating material.

The contact hole may be formed in the interlayer insulating layer 150. Accordingly, a part of the upper surface of the first active layer 120a and/or the second active layer 120b may be exposed by one contact hole, and further, a part of the upper surface of the first active layer 120a and/or the second active layer 120b may be exposed by another contact hole.

The first source electrode 161a, the first drain electrode 162a, the second source electrode 161b, and the second drain electrode 162b may be disposed on the interlayer insulating layer 150.

The first source electrode 161a may be electrically connected to one side of the first active layer 120a by a contact hole, and the first drain electrode 162a may be electrically connected to the other side of the first active layer 120a by a contact hole. In addition, the second source electrode 161b may be electrically connected to one side of the second active layer 120b by a contact hole, and the second drain electrode 162b may be electrically connected to the other side of the second active layer 120b by a contact hole.

The first source electrode 161a, the first drain electrode 162a, the second source electrode 161b, and the second drain electrode 162b may be formed of the same material as the first gate electrode 140a and/or the second gate electrode 140b, but are not limited thereto and may be formed of a material according to knowledge in the art.

According to one embodiment of the present disclosure, the first source electrode 161a may be connected to the first active layer 120a of the first thin film transistor TR1 through the contact hole, and the first source electrode 161a may be electrically connected to the upper organic light emitting element ELa disposed on the second surface 100b of the substrate 100.

In detail, a first contact hole CH1 overlapping with the via hole VH may be formed in the buffer layer 110, the gate insulating layer 130, and the interlayer insulating layer 150. The first contact hole CH1 exposes the via hole VH to the outside and may expose the upper first electrode 210 of the upper organic light emitting element ELa.

The first source electrode 161a may be electrically connected to the upper first electrode 210 of the upper organic light emitting element ELa exposed through the first contact hole CH1 and the via hole VH.

Therefore, according to one embodiment of the present disclosure, when the first thin film transistor TR1 disposed on the first surface 100a of the substrate 100 is driven, a voltage may be applied to the upper organic light emitting element ELa disposed on the second surface 100b of the substrate 100 through the first contact hole CH1 and the via hole VH.

The first planarization layer 171 may be formed on the first source electrode 161a, the first drain electrode 162a, the second source electrode 161b, and the second drain electrode 162b. The first planarization layer 171 may be formed on the first source electrode 161a, the first drain electrode 162a, the second source electrode 161b, and the second drain electrode 162b, thereby allowing the upper surface of the first planarization layer 171 to be planarized.

The first planarization layer 171 may be composed of an organic insulating layer material. The first planarization layer 171 may be composed of an organic insulating material such as, for example, an acrylic resin, an epoxy resin, a phenolic resin, a polyamide resin, or a polyimide resin.

The adhesive member 180 may be formed on the upper surface of the first planarization layer 171. The adhesive member 180 may have a function of adhering the lower encapsulation layer 191 to the substrate 100, and the adhesive member 180 may be, for example, a pressure sensitive adhesive PSA. Meanwhile, the adhesive member 180 is not limited thereto, and may be an optically clear adhesive or resin (OCA or OCR), and various materials may be used depending on the level of technology in the art.

The lower encapsulation layer 191 may be formed on the adhesive member 180. The lower encapsulation layer 191 may be formed by bonding on the first planarization layer 171 by the adhesive member 180. The lower encapsulation layer 191 may prevent moisture or oxygen in the air from flowing into the first thin film transistor TR1 or the second thin film transistor TR2. The lower encapsulation layer 191 may be a transparent material that transmits light, or may include a material with high reflectivity that reflects light.

According to one embodiment of the present disclosure, when the lower encapsulation layer 191 includes a material having a high reflectivity that reflects light, even if light emitted from the upper organic light emitting element ELa moves toward the first surface 100a of the substrate 100, it may be reflected by the lower encapsulation layer 191 and emitted toward the second surface 100b of the substrate 100. Accordingly, when the lower encapsulation layer 191 includes a material having a high reflectivity, the light emission efficiency of the display device according to one embodiment of the present disclosure may be improved.

Meanwhile, in FIG. 3, in order to protect the buffer layer 110, the first thin film transistor TR1, the second thin film transistor TR2, the gate insulating layer 130, the interlayer insulating layer 150 and the first planarization layer 171 formed in the first groove portion GP1 of the substrate 100, only the point that the lower encapsulation layer 191 is formed on the first surface 100a of the substrate 100 by the adhesive member 180 is illustrated, but is not limited thereto, and an encapsulation layer including a first encapsulation layer including an inorganic material, a second encapsulation layer including an organic material and a third encapsulation layer including an inorganic material may be formed on the first planarization layer 171 to prevent moisture or oxygen from entering the inside of the substrate 100. In this case, a counter substrate, encapsulation substrate, or cover glass CG facing the substrate 100 may be formed on the lower encapsulation layer 191. Furthermore, without being limited thereto, a polarizer may be formed instead of the lower encapsulation layer 191.

The upper organic light emitting element ELa is formed on the second surface 100b of the substrate 100. In detail, the upper organic light emitting element ELa is formed in each of the plurality of second groove portions GP2 formed on the second surface 100b of the substrate 100, and the upper organic light emitting element ELa formed in each of the plurality of second groove portions GP2 forms light and can configure the first sub pixel SP1 to the fourth sub pixel SP4.

Since the upper organic light emitting element ELa is formed in each of the plurality of second grooves GP2, moisture or air from the outside of the organic light emitting element ELa may be prevented from flowing into the upper emission layer 220 disposed in the upper organic light emitting element ELa, thereby reducing the lifespan of the sub pixel. Alternatively, the so-called fade-out phenomenon, which is a phenomenon in which the sub pixel darkens due to long-term use of the sub pixel, may be minimized or suppressed.

The upper organic light emitting element ELa includes an upper first electrode 210, an upper emission layer 220, and an upper second electrode 230. The upper first electrode 210 is formed on the second bottom surface BS2 of the second groove portion GP2. Since the upper first electrode 210 is disposed in the second groove portion GP2, the lower surface and the side surface of the upper first electrode 210 may be in contact with the substrate 100, respectively. In this case, one side surface and the other side surface of the upper first electrode 210, for example, the left side and the right side, may be perpendicular to the lower surface of the upper first electrode 210 according to the shape of the second groove portion GP2, but is not limited thereto.

The upper first electrode 210 may function as an anode electrode of the upper organic light emitting element ELa. The upper first electrode 210 may be electrically connected to the source electrode 161 of the first thin film transistor TR1 disposed in the first groove portion GP1 through a via hole VH connecting the first surface 100a and the second surface 100b of the substrate 100, specifically, through the via hole VH connecting the first bottom surface BS1 of the first groove portion GP1 and the second bottom surface BS2 of the second groove portion GP2.

The upper first electrode 210 can receive a signal transmitted from the first thin film transistor TR1 and be applied with a high potential voltage VDD, and in this case, the upper first electrode 210 can transmit holes to the upper emission layer 220.

The upper emission layer 220 is formed on the upper first electrode 210. In this case, the upper emission layer 220 may be formed by including red, green, and blue light emission tting layers patterned for each sub pixel, or may be formed by a white emission layer formed on all pixels. When the upper emission layer 220 is formed by a white emission layer, the emission layer 220 may be formed by including, for example, a first stack including a blue emission layer, for example, a second stack including a yellow-green emission layer, and a charge generation layer disposed between the first stack and the second stack, but is not necessarily limited thereto.

According to one embodiment of the present disclosure, the upper emission layer 220 may be pattern-formed without being connected to each other in the first sub pixel SP1 to the fourth sub pixel SP4. In detail, the upper emission layer 220 includes a first part 220a disposed in the second groove portion GP2 and a second part 220b disposed on the second upper surface TS2 and not disposed in the second groove portion GP2.

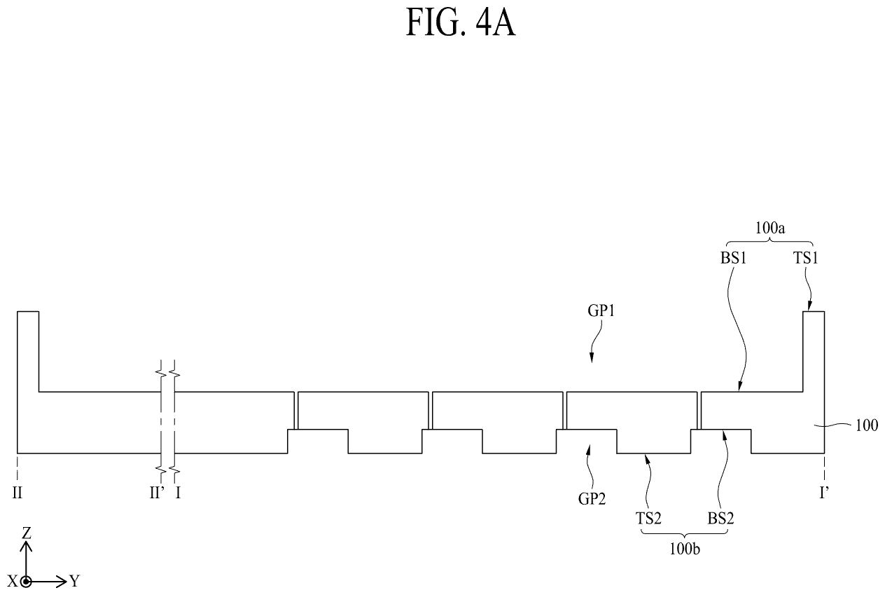

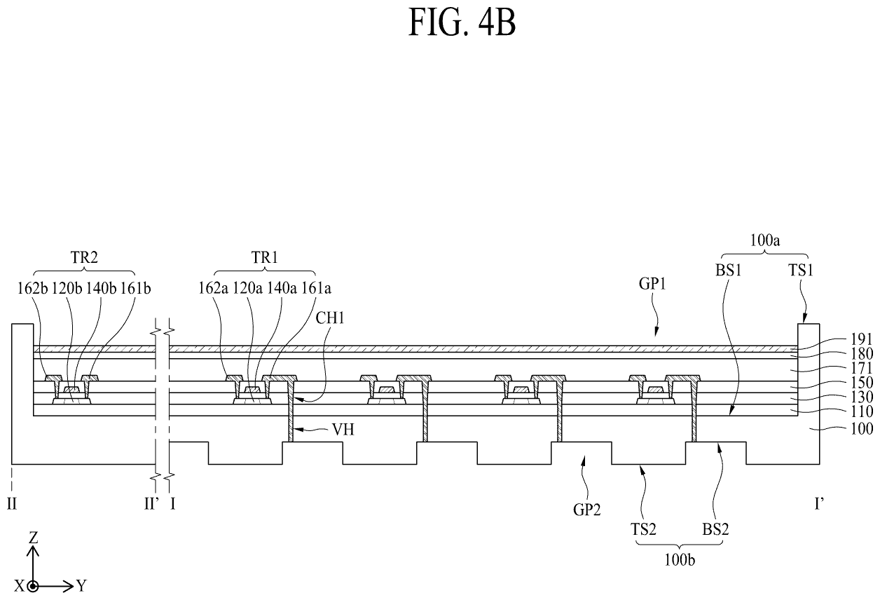

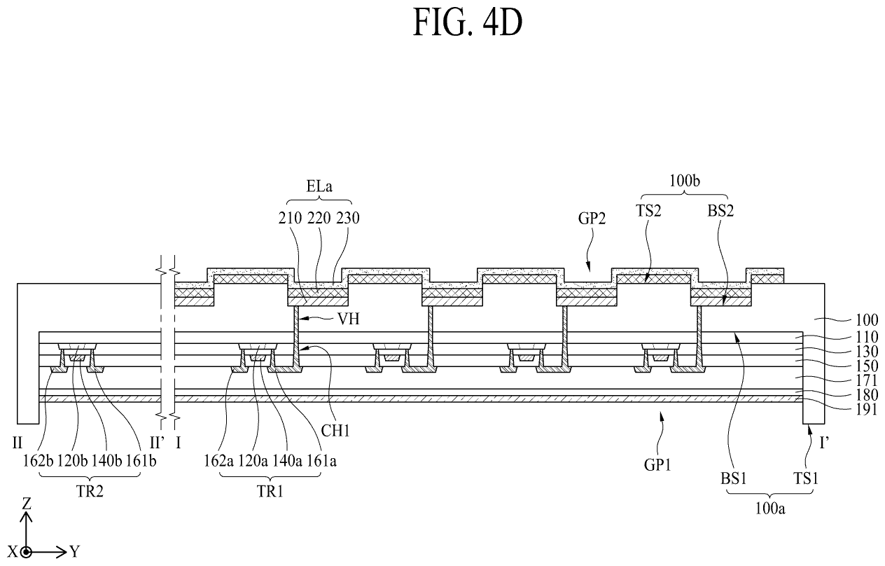

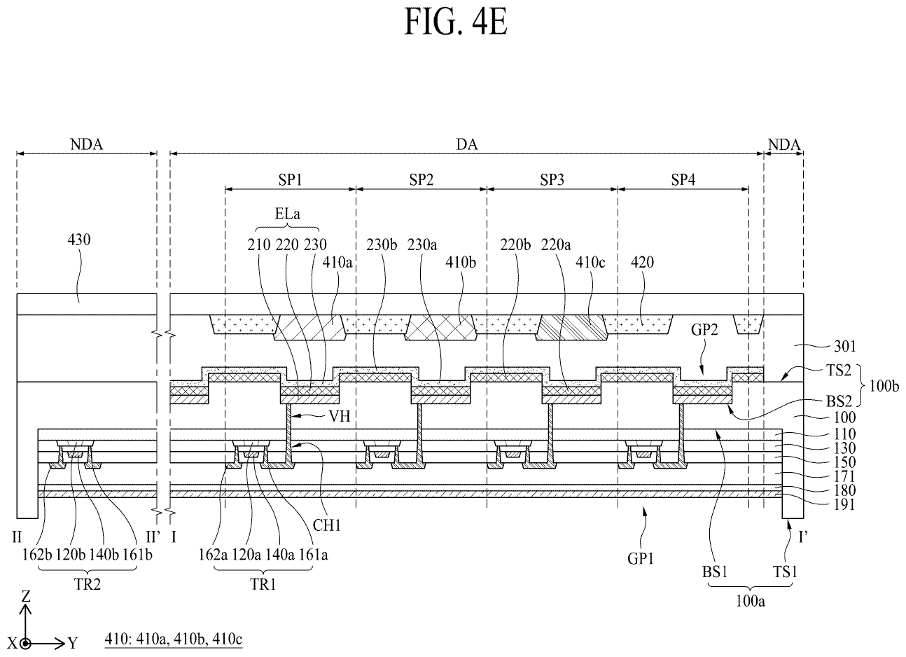

The first part 220a of the upper emission layer 220 is disposed in the second groove portion GP2 and may be formed at a lower position than the second surface 100b of the substrate 100. In detail, the upper surface of the first part 220a of the upper emission layer 220 may be formed at a lower position in the second direction Z than the second surface 100b of the substrate 100. By forming in this manner, the upper emission layer 220 may be pattern-formed without being connected to each other in the first sub pixel SP1 to the fourth sub pixel SP4. Meanwhile, this will be specifically described with reference to FIG. 4A to FIG. 4E.

The second part 220b of the upper emission layer 220 may not be disposed in the second groove portion GP2 and may be formed on the second upper surface TS2. In this case, the second part 220b of the upper emission layer 220 may be formed at a higher position than the second surface 100b of the substrate 100. The second part 220b of the upper emission layer 220 may be formed at a higher position than the first part 220a of the upper emission layer 220.

Since the first part 220a of the upper emission layer 220 is disposed in the plurality of second grooves GP2, and the second part 220b is not disposed in the plurality of second grooves 220b, the upper emission layer 220 may not be formed continuously on the second surface 100b of the substrate 100 but may be formed spaced apart from each other.

Since the upper emission layer 220 is not formed continuously in each of the first to fourth sub pixels SP1 to SP4, a problem of malfunction of the upper organic light emitting element ELa disposed in an adjacent sub pixel due to leakage current that occurs when the upper organic light emitting element ELa disposed in any one of the first to fourth sub pixels SP1 to SP4 is operated may not occur.

The upper second electrode 230 may be formed on the upper emission layer 220. The upper second electrode 230 may be formed in the second groove portion GP2 and may be provided to partially contact the second surface 100b of the substrate 100. The upper second electrode 230 may be a common electrode commonly formed in the first sub pixel SP1 to the fourth sub pixel SP4 and may function as a cathode.

Accordingly, the upper second electrode 230 can receive a low potential voltage VSS and transfer electrons to the upper emission layer 220. Meanwhile, although not specifically illustrated, the upper second electrode 230 may be connected to a low potential voltage line disposed in the first groove portion GP1 through a separate via hole that connects the first surface 100a and the second surface 100b of the substrate 100, and through this, the low potential voltage VSS may be applied to the upper second electrode 230.

The upper second electrode 230 may include a first portion 230a that overlaps the plurality of second grooves GP2 and a second portion 230b that overlaps another portion of the substrate 100 where the plurality of second grooves GP2 are not formed. In this case, the first portion 230a may be formed at a relatively lower position in the second direction Z than the second portion 230b. Accordingly, the height of the upper surface of the second portion 230b may be higher than the height of the upper surface of the first portion 230a.

The upper encapsulation layer 301 may be formed on the second electrode 230. The upper encapsulation layer 301 may be formed on the entire surface of the first substrate 100a.

The upper encapsulation layer 301 may be formed of acrylic resin, epoxy resin, polyimide, polyethylene (PE), or silicon oxycarbonate (SiOC).

Meanwhile, although not specifically illustrated, the upper encapsulation layer 301 may include a first encapsulation layer including an inorganic substance, a second encapsulation layer including an organic substance, and a third encapsulation layer including an inorganic substance.

The upper color filter 410 may be formed on the upper second electrode 230 by forming a pattern on each of the first sub pixel SP1, the second sub pixel SP2, and the third sub pixel SP3.

The upper color filter 410 can transmit light of a specific wavelength range of light emitted from the upper emission layer 220, thereby allowing the display device according to an embodiment of the present disclosure to display light of a specific wavelength range. For example, the upper color filter 410 includes a first upper color filter 410a, a second upper color filter 410b, and a third upper color filter 410c. In this case, the first upper color filter 410a, the second upper color filter 410b, and the third upper color filter 410c may be provided to correspond to the first sub pixel SP1 to the third sub pixel SP3, respectively.

The first upper color filter 410a can transmit one of red R, green G, and blue B light, for example, can transmit red R light. The second upper color filter 410b can transmit another of red R, green G, and blue B light, for example, can transmit green G light. The third upper color filter 410c can transmit another of red R, green G, and blue B light, for example, can transmit blue B light. Accordingly, the first sub pixel SP1 to the third sub pixel SP3 can display red R, green G, and blue B by the first upper color filter 410a to the third upper color filter 410c. However, it is not limited to this.

The upper black matrix 420 may be formed in an area between two adjacent sub pixels among the plurality of sub pixels SP1 to SP4. For example, the upper black matrix 420 may be formed on the upper second electrode 230 between the first sub pixel SP1 and the second sub pixel SP2. Alternatively, the upper black matrix 420 may be formed between the second sub pixel SP2 and the third sub pixel SP3 and between the third sub pixel SP3 and the fourth sub pixel SP4.

The upper black matrix 420 may be formed of a material that absorbs light of a wavelength in the visible light range. For example, the upper black matrix 420 may be formed of a black material, but is not limited thereto. By forming the upper black matrix 420 in this manner, the problem of light generated from two adjacent sub pixels among the plurality of sub pixels SP1 to SP4 being mixed and colored may be prevented.

The cover glass 430 may be formed on the upper color filter 410 and black matrix 420.

The cover glass 430 may be made of glass or plastic. In particular, the cover glass 430 may be made of transparent plastic having flexible property, for example, polyimide.

FIG. 4A to FIG. 4E are process cross-sectional views illustrating a method for manufacturing a display device according to one embodiment of the present disclosure. In this case, FIG. 4A to FIG. 4E relate to cross-sections I-I′ and II-II′ of FIG. 2B. Since the embodiments of FIG. 4A to FIG. 4E are process cross-sectional views for manufacturing a display device according to the embodiment of FIG. 3, the same components are given the same reference numerals, and repeated descriptions are omitted.

First, as may be seen in FIG. 4A, a portion of the first surface 100a and the second surface 100b of the substrate 100 may be removed to form the first groove portion GP1 and the plurality of second groove portions GP2. The first groove portion GP1 and the plurality of second groove portions GP2 of the substrate 100 may be formed by performing, for example, a deep reactive ion etching (DRIE) process or a deep reactive ion etching (DRIE) process and a wet etching process using a metal mask on a part of the substrate 100. Since the first groove portion GP1 and the plurality of second groove portions GP2 are formed using the deep reactive ion etching (DRIE) process and/or wet etching using the metal mask, the first groove portion GP1 and the plurality of second groove portions GP2 may be formed in a shape close to a right angle.

In detail, by forming the first groove portion GP1, the first surface 100a of the substrate 100 may include a first upper surface TS1 that does not overlap with the first groove portion GP1 and a first bottom surface BS1 that constitutes the bottom surface of the first groove portion GP1. In this case, an inner surface exposed from the substrate 100 may be formed between the first upper surface TS1 and the first bottom surface BS1 by forming the first groove portion GP1. According to one embodiment of the present disclosure, since the first groove portion GP1 is formed using the deep reactive ion etching (DRIE) process and/or wet etching using the metal mask, the inner surface of the substrate 100 on which the first groove portion GP1 is formed may be formed to form an angle close to a right angle with the first upper surface TS1 and/or the first bottom surface BS1.

Likewise, by forming the plurality of second grooves GP2, the second surface 100b of the substrate 100 may include a second upper surface TS2 that does not overlap with the plurality of second grooves GP2 and a second bottom surface BS2 that constitutes the bottom surface of the plurality of second grooves GP2. In this case, an inner surface exposed from the substrate 100 may be formed between the second upper surface TS2 and the second bottom surface BS2 by forming the plurality of second grooves GP2. According to one embodiment of the present disclosure, since the plurality of second grooves GP2 are formed using the deep reactive ion etching (DRIE) process and/or wet etching using the metal mask, the inner surface of the substrate 100 on which the plurality of second grooves GP2 are formed may be formed to form an angle close to a right angle with the second upper surface TS2 and/or the second bottom surface BS2.

The length of the first groove portion GP1 in the second direction Y may be formed to be greater than the length of the plurality of second groove portions GP2 in the second direction Y. By forming in this method, a plurality of thin film transistors, for example, the first thin film transistor (see TR1 of FIG. 3) and the second thin film transistor (see TR2 of FIG. 3), wiring for applying signals to the thin film transistors, electrodes, and integrated circuits, or the like. may be formed or mounted in the first groove portion GP1 of the substrate 100.

According to one embodiment of the present disclosure, a via hole VH may be additionally disposed in the substrate 100. In detail, the via hole VH may connect the first groove portion GP1 and the plurality of second groove portions GP2 of the substrate 100, respectively. Alternatively, the via hole VH may connect the first bottom surface BS1 of the substrate 100 and the second bottom surface BS2 of the substrate 100.

By being formed in this method, signals formed in the thin film transistor, wiring, electrode and integrated circuit formed or mounted in the first groove portion GP1 may be applied to the organic light emitting element disposed in each of the plurality of second groove portions GP2 through the via hole VH.

The via holes VH may be disposed to correspond to each of the plurality of second groove portions GP2. Accordingly, the via holes VH may be disposed along the plurality of second groove portions GP2 in the second direction Y and the third direction X.

The via hole VH may be formed after forming the first groove portion GP1 and the plurality of second groove portions GP2. In this case, the via hole VH may be formed, for example, by performing a Deep Reactive Ion Etching (DRIE) process or a Deep Reactive Ion Etching (DRIE) process and a Wet Etch process using a metal mask. Since the via hole VH is formed by using the Deep Reactive Ion Etching (DRIE) process and/or the Wet Etch process using the metal mask, the via hole VH may be formed in a shape close to a right angle.

Next, as may be seen in FIG. 4B, the buffer layer 110, the first thin film transistor TR1, the second thin film transistor TR2, the gate insulating layer 130, the interlayer insulating layer 150, the first planarization layer 171, the adhesive member 180, and the lower encapsulation layer 191 may be formed in the first home portion GP1.

Meanwhile, in FIG. 4B, the buffer layer 110, the gate insulating layer 130, and the interlayer insulating layer 150 are shown to be formed only on the first bottom surface BS1 of the substrate 100, but this is not limited thereto, and the buffer layer 110, the gate insulating layer 130, and the interlayer insulating layer 150 may also be formed on the inner surface of the substrate 100 formed by the first groove portion GP1 and the first upper surface TS1.

Looking a little more specifically into the formation process of the first thin film transistor TR1 and the second thin film transistor TR2, after forming the buffer layer 110, the active layer 120 may be formed on the buffer layer 110, after forming the active layer 120, the gate insulating layer 130 may be formed, after forming the gate insulating layer 130, the gate electrode 140 may be formed, and after forming the gate electrode 140, the interlayer insulating layer 150 may be formed. In addition, a contact hole may be formed to connect the source electrode 161 and the drain electrode 162 with the active layer 120 and the via hole VH. In this case, a contact hole may be formed by removing a portion of the gate insulating layer 130 and the interlayer insulating layer 150 so that one side and the other side of the active layer 120 may be exposed to the outside, and a first contact hole CH1 connected to the via hole VH may be formed by removing a portion of the buffer layer 110, the gate insulating layer 130 and the interlayer insulating layer 150. Thereafter, the source electrode 161 and the drain electrode 162 may be formed so as to implement the first thin film transistor TR1 and the second thin film transistor TR2.

Next, as may be seen in FIG. 4c, in order to form an upper organic light emitting element (see ELa of FIG. 3) in the plurality of second groove portions GP2, the substrate 100 may be flipped over so that the second surface 100b of the substrate 100 faces upward in the drawing. In the case where the substrate 100 is flipped over, the first groove portion GP1 faces downward in the drawing, and the plurality of second groove portions GP2 may be disposed to face upward in the drawing.

Next, as may be seen in FIG. 4D, the upper organic light emitting element ELa may be formed in the plurality of second groove portions GP2. In detail, the upper first electrode 210 may be formed on the second bottom surface BS2 of the substrate 100. In this case, the upper first electrode 210 may be formed, for example, using sputtering. The upper first electrode 210 may be pattern-formed using a separate mask after being formed on the entire surface of the second surface 100b of the substrate 100. The upper first electrode 210 may be electrically connected to the source electrode 161 of the first thin film transistor TR1 disposed in the first groove portion GP1 through the via hole VH and the first contact hole CH1.

The upper emission layer 220 may be formed on the upper first electrode 210. The upper emission layer 220 may be deposited by an evaporator. The upper emission layer 220 is deposited by an evaporator. According to one embodiment of the present disclosure, when the upper emission layer 220 is deposited by an evaporator, since the plurality of second grooves GP2 are formed in a shape close to a right angle, the upper emission layer 220 is not formed continuously on the second surface 100b of the substrate 100.

In detail, a part of the upper emission layer 220 disposed inside the plurality of second grooves GP2 among the upper emission layers 220 and another part of the upper emission layer 220 disposed on the second upper surface TS2 are formed so as to be spaced apart from each other rather than being continuous with each other. By forming in this method, when the upper organic light emitting element ELa disposed in any one of the first sub pixel (see SP1 of FIG. 3) to the fourth sub pixel (see SP4 of FIG. 4) is operated, a problem of malfunction of the upper organic light emitting element ELa disposed in another adjacent sub pixel may not occur.

The upper second electrode 230 may be formed on the upper emission layer 220. The upper second electrode 230 may be formed to overlap the entirety of the plurality of second groove portions GP2.

The upper second electrode 230 may be formed, for example, by sputtering. Accordingly, the upper second electrode 230 may be formed on the entire surface 100b of the substrate 100 without being interrupted by the plurality of second grooves GP2.

Finally, as may be seen in FIG. 4E, an upper color filter 410, an upper black matrix 420, and a cover glass 430 may be formed on the upper organic light emitting element ELa.

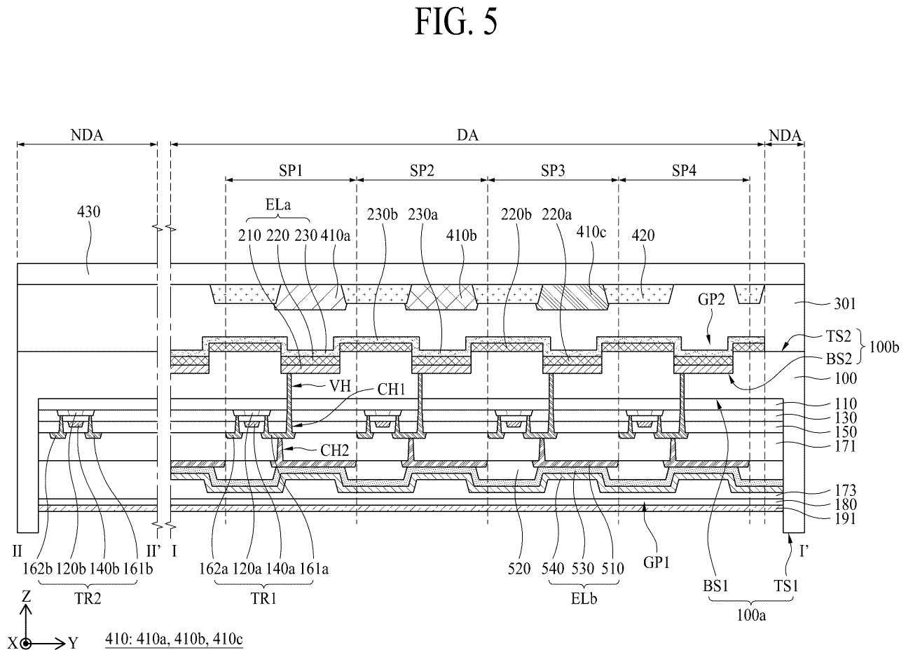

FIG. 5 is a cross-sectional view of a display device according to another embodiment of the present disclosure. In this case, FIG. 5 relates to cross-sections I-I′ and II-II′ of FIG. 2B. Meanwhile, FIG. 5 is identical to the embodiment of FIG. 3 except for the configuration of the lower organic light emitting element disposed on the first surface of the substrate, and therefore, the following description will focus on the different configuration.

As may be seen in FIG. 5, a display device according to another embodiment of the present disclosure may include a substrate 100, a buffer layer 110, a first thin film transistor TR1, a second thin film transistor TR2, a gate insulating layer 130, an interlayer insulating layer 150, a first planarization layer 171, a lower organic light emitting element ELb, a second planarization layer 173, an adhesive member 180, a lower encapsulation layer 191, an upper organic light emitting element ELa, an upper color filter 410, an upper black matrix 420, and a cover glass 430.

According to another embodiment of the present disclosure, the buffer layer 110, the first thin film transistor TR1, the second thin film transistor TR2, the gate insulating layer 130, the interlayer insulating layer 150, the first planarization layer 171, the lower organic light emitting element ELb, the second planarization layer 173, the adhesive member 180, and the lower encapsulation layer 191 may be disposed in a first groove portion GP1 formed on the first surface 100a of the substrate 100.

Furthermore, the upper organic light emitting element ELa, the upper color filter 410, the upper black matrix 420, and the cover glass 430 may be formed on the second surface 100b of the substrate 100. In detail, the upper organic light emitting element ELa may be disposed inside the second groove portion GP2 formed on the second surface 100b, and the upper black matrix 420, the upper color filter 410, and the cover glass 430 may be disposed on the second surface 100b of the substrate 100.

A second contact hole CH2 may be formed in the first planarization layer 171. The second contact hole CH2 may be formed in each of the first sub pixel SP1 to the fourth sub pixel SP4 to expose the upper surface of the source electrode 161 of the first thin film transistor TR1.

The lower organic light emitting element ELb may be formed on the first planarization layer 171. According to an embodiment of the present disclosure, the lower organic light emitting element ELb may be provided to overlap the upper organic light emitting element ELa. The upper organic light emitting element ELa and the lower organic light emitting element ELb disposed in each of the first to fourth sub pixels SP1 to SP4 may be electrically connected to the first thin film transistor TR1, thereby receiving the same signal. The upper organic light emitting element ELa and the lower organic light emitting element ELb disposed in any one sub pixel among the first to fourth sub pixels SP1 to SP4 may equally express any one color among red R, green G, blue B, and white W.

The lower organic light emitting element ELb is composed of a lower first electrode 510, a bank layer 520, a lower emission layer 530, and a lower second electrode 540.

The lower first electrode 510 may be formed on the second planarization layer 173 and may be electrically connected to the source electrode 161 of the first thin film transistor TR1 through the second contact hole CH2 disposed in the second planarization layer 173. The lower first electrode 510 may function as an anode.

The lower first electrode 510 is pattern-formed on the second planarization layer 173, and may be pattern-formed to correspond to the first sub pixel SP1 to the fourth sub pixel SP4. The lower first electrode 510 may be disposed to overlap the upper first electrode 210.

According to one embodiment of the present disclosure, the lower first electrode 510 may have a different structure from the upper first electrode 210. In detail, the angle formed by the lower surface and the side surface of the lower first electrode 510 may be different from the angle formed by the lower surface and the side surface of the upper first electrode 210. In detail, the angle formed by the lower surface and the side surface of the lower first electrode 510 may be smaller than the angle formed by the lower surface and the side surface of the upper first electrode 210.

According to one embodiment of the present disclosure, the lower first electrode 510 may be a transparent electrode. Since the lower first electrode 510 is formed of a transparent electrode, light emitted from the lower organic light emitting element ELb is directed toward the second surface 100b of the substrate 100, thereby increasing the amount of light emitted toward the second surface 100b, thereby implementing a display device in which light efficiency or brightness is improved by the upper organic light emitting element ELa and the lower organic light emitting element ELb.

The bank layer 520 may be formed on the lower first electrode 510. In this case, a portion of the upper surface of the lower first electrode 510 that is exposed and not covered by the bank layer 520 becomes a light emitting area.

The bank layer 520 may be formed of an organic film such as an acrylic resin, an epoxy resin, a phenolic resin, a polyamide resin, or a polyimide resin. Meanwhile, the bank layer 520 may also be formed by including a black material.

The lower emission layer 530 may be formed on the lower first electrode 510. The lower emission layer 530 may include red, green, and blue emission layers patterned for each sub pixel, or may be formed of a white emission layer connected to all pixels. When the lower emission layer 530 is formed of a white emission layer, the lower emission layer 530 may include, but is not necessarily limited to, a first stack including a blue emission layer, a second stack including, for example, a yellow-green emission layer, and a charge generation layer disposed between the first stack and the second stack.

The lower emission layer 530 may be formed continuously in the first sub pixel SP1 to the fourth sub pixel SP4. The lower emission layer 530 may be formed with a different structure from the upper emission layer 220.

The lower second electrode 540 may be formed on the lower emission layer 530. The lower second electrode 540 may function as a cathode.

The lower second electrode 540 may be formed, for example, on the bank layer 520 and the lower emission layer 530. Accordingly, the lower second electrode 540 may be formed over the entire surface of the first sub pixel SP1 to the fourth sub pixel SP4.

The third planarization layer 175 may be formed on the lower organic light emitting element ELb. In detail, the third planarization layer 175 may be formed on the lower second electrode 540. The third planarization layer 175 may be composed of an organic insulating layer material. The third planarization layer 175 may be composed of an organic insulating material, such as, for example, an acrylic resin, an epoxy resin, a phenolic resin, a polyamide resin, or a polyimide resin.

In this case, the adhesive member 180 may be formed on the upper surface of the third planarization layer 175.

The lower encapsulation layer 191 is formed by including a material having high reflectivity. The lower encapsulation layer 191 may be formed by including, for example, one of a nickel-based metal including nickel or a nickel alloy, an iron-based metal including iron or an iron alloy, and a stainless steel metal.

According to one embodiment of the present disclosure, when the lower encapsulation layer 191 includes a material having a high reflectivity that reflects light, even if light emitted from the upper organic light emitting element ELa and the lower organic light emitting element ELb moves toward the first surface 100a of the substrate 100, it may be reflected by the lower encapsulation layer 191 and emitted toward the second surface 100b of the substrate 100. Therefore, when the lower encapsulation layer 191 includes a material having a high reflectivity, the light emission efficiency of the display device according to one embodiment of the present disclosure may be improved.

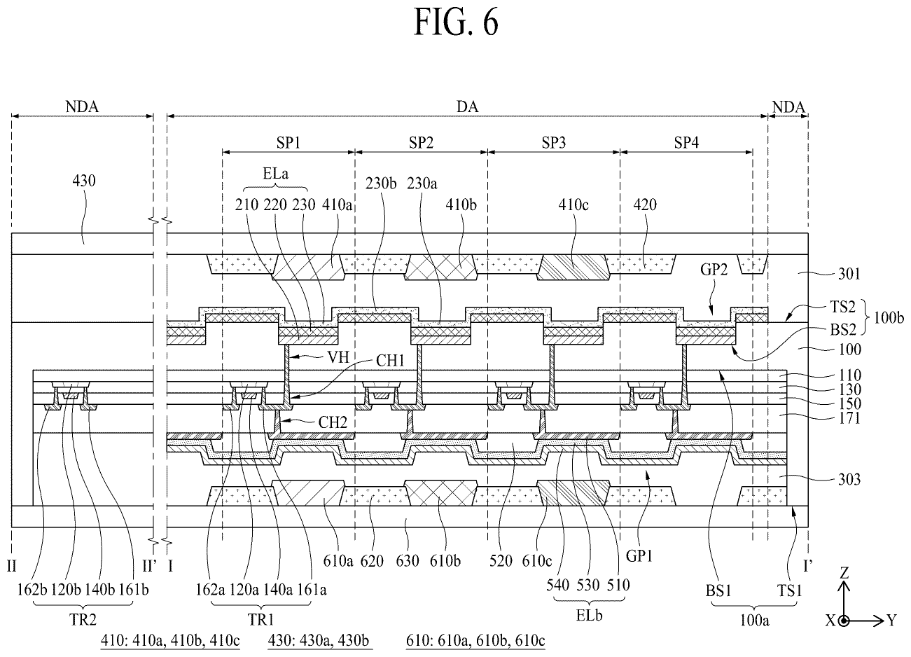

FIG. 6 is a cross-sectional view of a display device according to another embodiment of the present disclosure. In this case, FIG. 6 relates to cross-sections I-I′ and II-II′ of FIG. 2B. Meanwhile, the embodiment of FIG. 6 is identical to the embodiment of FIG. 5 except for the configurations of the encapsulation layer, the lower color filter, the black matrix, and the second cover glass, so the following description will focus on the different configurations.

As may be seen in FIG. 6, a display device according to another embodiment of the present disclosure is configured to additionally include the lower organic light emitting element ELb, the lower encapsulation layer 303, the lower color filter 610, the lower black matrix 620, and the second cover glass 630 on the second surface 100b of the substrate 100.

The lower encapsulation layer 303 may be formed on the lower organic light emitting element ELb. In detail, the lower encapsulation layer 303 may be formed on the lower second electrode 340 of the lower organic light emitting element ELb. According to another embodiment of the present disclosure, since the lower encapsulation layer 303 is formed on the lower organic light emitting element ELb, light generated from the lower organic light emitting element ELb is emitted through the first surface 100a of the substrate 100, so that the upper organic light emitting element ELa displays the second surface 100b of the substrate 100, and the lower organic light emitting element ELb displays the first surface 100a of the substrate 100, so that a double-sided emission display device may be implemented.

The lower encapsulation layer 303 may be formed across the display area DA and the non-display area NDA, and in this case, the lower encapsulation layer 303 may be formed on the entire surface of the first groove portion GP1. Meanwhile, the present disclosure is not limited thereto, and the lower encapsulation layer 303 may be formed only in the display area DA and may be omitted in the non-display area NDA.

The lower encapsulation layer 303 may be formed of acrylic resin, epoxy resin, polyimide, polyethylene (PE), or silicon oxycarbonate (SiOC).

Meanwhile, although not specifically illustrated, the lower encapsulation layer 303 may include a first encapsulation layer including an inorganic substance, a second encapsulation layer including an organic substance, and a third encapsulation layer including an inorganic substance.

The lower color filter 610 and the lower black matrix 620 may be formed on the lower encapsulation layer 303.

The lower color filter 610 may be formed on the upper second electrode 230 by forming a pattern on each of the first sub pixel SP1, the second sub pixel SP2, and the third sub pixel SP3.

The lower color filter 610 can transmit light of a specific wavelength range of light emitted from the upper emission layer 220, thereby allowing the display device according to an embodiment of the present disclosure to display light of a specific wavelength range. For example, the lower color filter 610 includes a first lower color filter 610a, a second lower color filter 610b, and a third lower color filter 610c. In this case, the first lower color filter 610a, the second lower color filter 610b, and the third lower color filter 610c may be disposed to correspond to the first sub pixel SP1 to the third sub pixel SP3, respectively.

The first lower color filter 610a can transmit one of red R, green G, and blue B light, for example, can transmit red R light. The second lower color filter 610b can transmit another of red R, green G, and blue B light, for example, can transmit green G light. The third lower color filter 610c can transmit another of red R, green G, and blue B light, for example, can transmit blue B light. Accordingly, the first sub pixel SP1 to the third sub pixel SP3 can display red R, green G, and blue B by the first lower color filter 610a to the third lower color filter 610c. However, it is not limited to this.

The lower black matrix 620 may be formed in an area between two adjacent sub pixels among the plurality of sub pixels SP1 to SP4. For example, the lower black matrix 620 may be formed on the lower encapsulation layer 303 between the first sub pixel SP1 and the second sub pixel SP2. Alternatively, the lower black matrix 620 may be formed between the second sub pixel SP2 and the third sub pixel SP3 and between the third sub pixel SP3 and the fourth sub pixel SP4.

The lower black matrix 620 may be formed of a material that absorbs light of a wavelength in the visible light range. For example, the lower black matrix 620 may be formed of a black material, but is not limited thereto. By forming the lower black matrix 620 in this manner, the problem of light generated from two adjacent sub pixels among the plurality of sub pixels SP1 to SP4 being mixed and colored may be prevented.

The cover glass 630 may be formed on the lower color filter 610 and the lower black matrix 620. The cover glass 630 may be a plastic film or an organic substrate, but is not limited thereto. The cover glass 630 may be omitted in some cases.

Meanwhile, in FIG. 6, the cover glass 630 is shown in contact with the first surface 100a of the substrate 100, for example, the first upper surface TS1, but is not limited thereto, and the cover glass 630 may be disposed in the first groove portion GP1, so that one surface of the cover glass 630, for example, the lower surface, may be formed at a position lower than the first upper surface TS1 of the substrate 100.

FIG. 7 is a plan view of a display device according to another embodiment of the present disclosure. Meanwhile, the embodiment of FIG. 7 is identical to the embodiment of FIG. 1B except for the configuration of the contact portion, so the following description will focus on the different configuration.

As may be seen from FIG. 7, a display device according to another embodiment of the present disclosure includes a display panel 10. In this case, the display panel 10 includes a substrate 100 and a contact unit CNT disposed on the substrate 100, a data driving unit 720, a timing control unit 730, a first signal line SL1, and a second signal line SL2.

According to another embodiment of the present disclosure, the contact unit CNT, the data driving unit 720, the timing control unit 730, the first signal line SL1 and the second signal line SL2 may be disposed in a concave portion of the first surface 100a of the substrate 100. In detail, the contact unit CNT, the data driving unit 720, the timing control unit 730, the first signal line SL1 and the second signal line SL2 may be formed in the first groove unit GP1. By forming them in this manner, the contact unit CNT, the data driving unit 720, the timing control unit 730, the first signal line SL1 and the second signal line SL2 are formed inside the substrate 100, thereby making it possible to implement a thin height or thickness in the first direction Z of the display device according to another embodiment of the present disclosure.

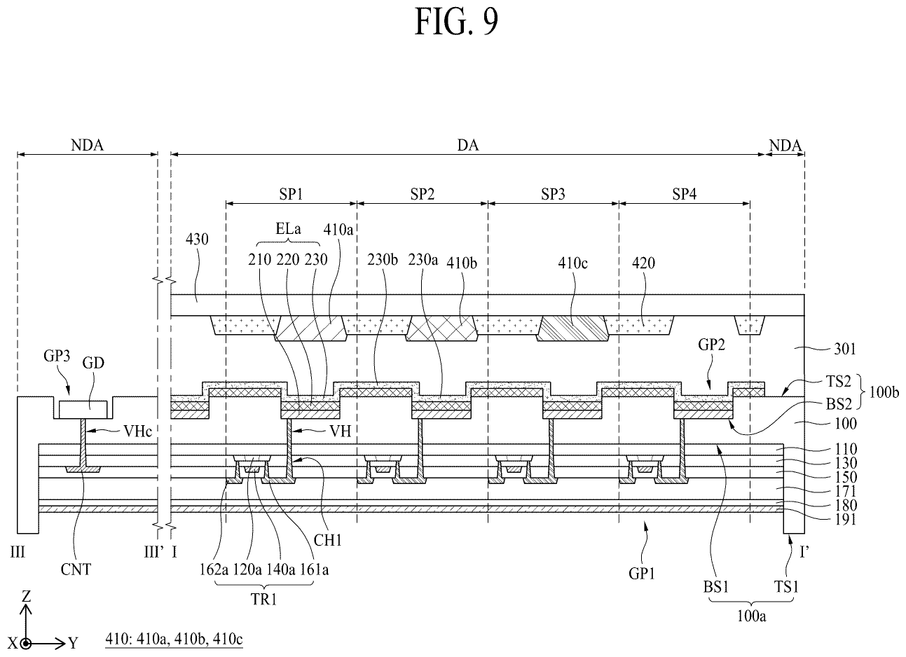

According to another embodiment of the present disclosure, the contact portion CNT may be electrically connected to a gate driver integrated circuit (see GD of FIG. 9) disposed on the second surface 100b of the substrate 100. The contact portion CNT may be connected to the second signal line SL2 and transmit a signal received from the gate driver integrated circuit (GD of FIG. 9) to the second signal line SL2.

FIG. 8 is a plan view of a display device according to another embodiment of the present disclosure. Meanwhile, since the embodiment of FIG. 8 relates to the same embodiment as the embodiment of FIG. 7, a repeated description will be omitted.

As may be seen from FIG. 8, a display device according to another embodiment of the present disclosure may include a display panel 10, and a plurality of second grooves GP2 formed by removing a portion of a second surface 100b of the substrate 100 may be disposed on the back surface of the display panel 10. An organic light emitting element may be formed in the plurality of second grooves GP2. Accordingly, the plurality of second grooves GP2 may form a plurality of pixels P.

Each of the plurality of pixels P may include a first sub pixel SP1 to a fourth sub pixel SP4.

Since the plurality of pixels P are disposed in the plurality of second grooves GP2 formed on the second surface 100b of the substrate 100, the thickness of the display device according to one embodiment of the present disclosure may be implemented thinly.

As may be seen in FIG. 8, the plurality of second grooves GP2 are disposed in the second direction Y and the third direction X on the second surface 100b of the substrate 100. Accordingly, the plurality of pixels P disposed in the plurality of second grooves GP2 may be arranged along the second direction Y and the third direction X on the second surface 100b of the substrate 100. In this case, the plurality of pixels P can include a first sub pixel SP1, a second sub pixel SP2, a third sub pixel SP3, and a fourth sub pixel SP4 that display different colors. An organic light emitting element may be formed in one of the second grooves GP2 among the plurality of second grooves GP2, and the one of the second grooves GP2 in which the organic light emitting element is formed may constitute one of the sub pixels among the first sub pixel SP1 to the fourth sub pixel SP4.

The plurality of pixels P may include a first sub pixel SP1 to a fourth sub pixel SP4. The first sub pixel SP1 to the fourth sub pixel SP4 may, for example, display red R, green G, blue B, and white W, respectively, but are not limited thereto, and the color and arrangement of light displayed by the first sub pixel SP1 to the fourth sub pixel SP4 may be variously changed according to common sense in the art.

According to another embodiment of the present disclosure, the plurality of second grooves GP2 are formed in the display area DA, and the plurality of second grooves GP2 may not be formed in the non-display area NDA. Although not specifically illustrated, the first signal line (see SL1 of FIG. 7) and the second signal line (see SL2 of FIG. 7) may be provided to correspond to an area where they intersect each other. In this case, signals applied from the first signal line (see SL1 of FIG. 8) and the second signal line (see SL2 of FIG. 8) may drive the organic light emitting element disposed in the second grooves GP2, so that the plurality of pixels P may display an image.

According to another embodiment of the present disclosure, a third groove GP3 may be additionally formed on one side, for example, the left side, of the plurality of second grooves GP2 on the second surface 100b of the substrate 100. The third groove GP3 may be formed by removing a portion of the substrate 100.

In addition, a gate driver integrated circuit GD may be disposed in the third groove GP3. The gate driver integrated circuit GD may be mounted in the third groove GP3 in the form of an integrated circuit. In this case, the gate driver integrated circuit GD may apply a signal to a contact portion (see CNT in FIG. 7) disposed on the first surface 100a of the substrate 100 through a contact via hole (see VHc in FIG. 9).

The gate driver integrated circuit GD can apply various gate signals for driving the plurality of pixels P. The gate driver integrated circuit GD sequentially supplies gate pulses to the second signal lines SL2, for example, gate lines GL, through the contact unit CNT for one frame by using a start signal and a gate clock, etc. transmitted from the timing control unit 730. Here, one frame refers to a period during which one image is output through the display panel 10. The gate pulse has a turn-on voltage capable of turning on a switching element (thin film transistor) disposed in a circuit for driving the pixels.

In addition, the gate driver integrated circuit GD supplies a gate off signal capable of turning off a switching element to the second signal line SL2, for example, a gate line, during the remaining period during which the gate pulse is not supplied during one frame. The gate pulse and the gate off signal may be collectively referred to as a gate signal GS.

According to another embodiment of the present disclosure, a thin display device may be implemented by mounting the gate driver integrated circuit GD in the third groove GP3.

FIG. 9 is a cross-sectional view of a display device according to another embodiment of the present disclosure. In this case, FIG. 9 relates to cross-sections I-I′ and III-III′ of FIG. 8. Meanwhile, the embodiment of FIG. 9 is identical to the embodiment of FIG. 3 except for the configuration disposed in the non-display area, so the following description will focus on the different configuration.

As may be seen in FIG. 9, a display device according to another embodiment of the present disclosure may include a substrate 100, a buffer layer 110, a first thin film transistor TR1, a contact portion CNT, a gate insulating layer 130, an interlayer insulating layer 150, a first planarization layer 171, an adhesive member 180, a lower encapsulation layer 191, an upper organic light emitting element ELa, an upper color filter 410, an upper black matrix 420, a cover glass 430, and a gate driver integrated circuit GD.

According to another embodiment of the present disclosure, the buffer layer 110, the first thin film transistor TR1, the contact portion CNT, the gate insulating layer 130, the interlayer insulating layer 150, the first planarization layer 171, the adhesive member 180, and the lower encapsulation layer 191 may be disposed in the first groove portion GP1 formed on the first surface 100a of the substrate 100. Furthermore, the upper organic light emitting element ELa, the upper color filter 410, the upper black matrix 420, and the cover glass 430 may be formed on the second surface 100b of the substrate 100.

In detail, the upper organic light emitting element ELa may be disposed inside the second groove portion GP2 formed on the second surface 100b, the upper color filter 410, the upper black matrix 420 and the step compensation layer 430 may be disposed on the second surface 100b of the substrate 100, and the gate driver integrated circuit GD may be disposed inside the third groove portion GP3.

A first groove portion GP1 overlapping a non-display area NDA and a display area DA is formed on a first surface 100a of the substrate 100, a plurality of second groove portions GP2 overlapping the display area DA but not overlapping the non-display area NDA may be formed on a second surface 100b of the substrate 100, and a third groove portion GP3 overlapping the non-display area NDA but not overlapping the display area DA may be formed on the second surface 100b of the substrate 100.

The third groove portion GP3 may overlap the first groove portion GP1, and the first groove portion GP1 and the third groove portion GP3 may be connected to each other through a contact via hole VHc formed in the substrate 100. According to another embodiment of the present disclosure, the contact portion CNT disposed in the first groove portion GP1 and the gate driver integrated circuit GD disposed in the third groove portion GP3 may be electrically connected to each other through the contact via hole VHc.

The contact portion CNT can receive an electrical signal from the gate driver integrated circuit GD and transmit the gate signal to the gate electrode 140 of the first thin film transistor TR1 disposed in the first groove portion GD1. Meanwhile, in FIG. 10, the contact portion CNT is illustrated as being positioned between the gate insulating layer 130 and the interlayer insulating layer 150, but is not limited thereto and may be formed in various positions depending on the level of technology in the art.

Although the embodiments of the present disclosure have been described in more detail with reference to the attached drawings, the present disclosure is not necessarily limited to these embodiments, and various modifications may be made without departing from the technical idea of the present disclosure. Accordingly, the embodiments disclosed in the present disclosure are not intended to limit the technical idea of the present disclosure, but to explain it, and the scope of the technical idea of the present disclosure is not limited by these embodiments. Therefore, it should be understood that the embodiments described above are exemplary in all aspects and not restrictive. The protection scope of the present disclosure should be interpreted by the claims, and all technical ideas within a scope equivalent thereto should be interpreted as being included in the scope of the rights of the present disclosure.

According to the present disclosure as described above, the following effects are achieved.

According to one embodiment of the present disclosure, a thin display device may be implemented by forming a thin film transistor, wiring, and electrode for driving a pixel in a first groove portion on a first surface of a substrate, and forming a pixel in a second groove portion on a second surface of the substrate.

According to one embodiment of the present disclosure, a double-sided light emitting display device may be implemented by forming a lower organic light emitting element in a first groove portion of a first surface of a substrate and forming an upper organic light emitting element in a second groove portion of a second surface of the substrate.

According to one embodiment of the present disclosure, by forming a lower organic light emitting element in a first groove portion of a first surface of a substrate and forming an upper organic light emitting element in a second groove portion of a second surface of the substrate, the efficiency of light emitted to the second surface of the substrate may be improved.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a first groove on a first surface and a second groove on a second surface opposite to the first surface;
a thin film transistor disposed in the first groove of the substrate; and
an upper organic light emitting element disposed in the second groove of the substrate,
wherein the thin film transistor and the upper organic light emitting element are electrically connected through a via hole, and
wherein the via hole is formed to penetrate the first groove and the second groove.

2. The display device of claim 1, wherein the upper organic light emitting element includes:
a first electrode connected to the via hole;
an emission layer on the first electrode; and
a second electrode on the emission layer, and
wherein a portion of the second electrode is disposed in the second groove of the substrate.

3. The display device of claim 2, wherein a side surface or a bottom surface of the first electrode is in contact with the substrate.

4. The display device of claim 2, wherein a side surface of the emission layer is in contact with the substrate.

5. The display device of claim 2, wherein a portion of the second electrode is in contact with the second surface of the substrate.

6. The display device of claim 2, wherein a portion of a bottom surface of the second electrode is formed perpendicularly along the second groove.

7. The display device of claim 2 further comprising a color filter and a black matrix on the second electrode,
wherein the color filter overlaps the second groove.

8. The display device of claim 1 further comprising a lower organic light emitting element disposed on the thin film transistor and electrically connected to the thin film transistor,
wherein the lower organic light emitting element includes:
a third electrode;
a second emission layer on the third electrode; and
a fourth electrode on the second emission layer.

9. The display device of claim 8, wherein the upper organic light emitting element and the lower organic light emitting element correspond to each other.

10. The display device of claim 8, wherein the upper organic light emitting element and the lower organic light emitting element receive the same signal via the thin film transistor.

11. The display device of claim 8, wherein the upper organic light emitting element includes:
a first electrode connected to the via hole;
an emission layer on the first electrode; and
a second electrode on the emission layer, and
wherein an angle formed by a bottom surface of the first electrode and side surface of the first electrode a right angle is greater than an angle formed by the bottom surface of the third electrode and side surface of the third electrode an acute angle.

12. The display device of claim 8 further comprising an encapsulation layer disposed on the thin film transistor,
wherein the encapsulation layer includes a reflective material.

13. A display device, comprising:
a substrate including a first groove on a first surface and two or more second grooves on a second surface opposite to the first surface;
a thin film transistor disposed in the first groove of the substrate; and
a first light emitting element and a second light emitting element respectively disposed in adjacent second grooves,
wherein each of the first light emitting element and second light emitting element includes:
a first electrode disposed in the second groove;
an emission layer on the first electrode; and
a second electrode on the emission layer, and
wherein the second electrodes of the first light emitting element and second light emitting element are continuously formed.

14. The display device of claim 13, wherein the second electrodes continuously formed in the first emitting element and second light emitting element are in contact with the second surface of the substrate.

15. The display device of claim 13 further comprising a black matrix disposed between the first and second light emitting elements,
wherein the black matrix overlaps the substrate between the second groove in which the first light emitting element is provided and the second groove in which the second light emitting element is provided.

16. The display device of claim 15 further comprising a third light emitting element and a fourth light emitting element disposed in the first groove,
wherein each of the third light emitting element and fourth light emitting element includes:
a third electrode disposed on the thin film transistor;
a second emission layer on the third electrode;
a fourth electrode on the second emission layer; and
a bank defining the third light emitting element and fourth light emitting element, and
wherein the bank between the third light emitting element and fourth light emitting element overlaps the black matrix between the first light emitting element and second light emitting element.

17. A display device, comprising:
a substrate defining a display area and a non-display area;
a plurality of subpixels disposed in the display area and a first thin film transistor configured to drive the plurality of subpixels; and
a gate driver circuit disposed in the non-display area,
wherein the first thin film transistor is disposed in a first groove on a first surface of the substrate,
wherein the plurality of subpixels are respectively disposed in a plurality of second grooves on a second surface of the substrate, and
wherein the first thin film transistor and the plurality of subpixels are electrically connected through a via hole that connects the first groove and the plurality of second grooves.

18. The display device of claim 17, wherein the gate driver circuit includes a second thin film transistor configured to apply a signal to a gate electrode of the first thin film transistor, and
wherein the second thin film transistor is disposed in the first groove.

19. The display device of claim 17 further comprising a third groove disposed in the non-display area and on the second surface of the substrate,
wherein the gate driver circuit includes a gate driver integrated circuit, and
wherein the gate driver integrated circuit is mounted in the third groove.

20. The display device of claim 19 further comprising a contact part disposed in the first groove in the non-display area and configured to apply a gate signal of the gate driver integrated circuit to the first thin film transistor,
wherein the contact part is electrically connected to the gate driver integrated circuit through a contact via hole.
